(19) United States
(12) Patent Application Publication
(10) Pub. No.: US 2008/0163916 A1
(43) Pub. Date: Jul. 10, 2008

(54) THERMOELECTRIC CONVERSION MODULE AND THERMOELECTRIC CONVERSION APPARATUS

(75) Inventors: Osamu Tsuneoka, Tokyo (JP); Naruhito Kondo, Kawasaki-Shi (JP); Akihiro Hara, Yokohama-Shi (JP); Kazuki Tateyama, Yokohama-Shi (JP); Takahiro Sogou, Yokohama-Shi (JP); Yasuhito Saito, Yokohama-Shi (JP); Masayuki Arakawa, Yokohama-Shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: KABUSHIKI KAISHA TOSHIBA, TOKYO (JP)

(21) Appl. No.: 11/876,399

(22) Filed: Oct. 22, 2007

(30) Foreign Application Priority Data
Oct. 25, 2006 (JP) 2006-290191

(51) Int. Cl. H01L 35/28; H01L 35/02; F25B 21/02

(52) U.S. Cl. 136/203; 136/200; 136/230; 62/3.2

(57) ABSTRACT

According to one embodiment, a thermoelectric conversion module includes a thermoelectric conversion portion, a first external electrode, and a second external electrode. The thermoelectric conversion portion includes a single thermoelectric conversion portion element, or electrically connected thermoelectric conversion portion elements. The thermoelectric conversion portion element includes a high temperature electrode, low temperature electrodes, and an n-type and a p-type thermoelectric conversion semiconductor layer disposed between the high temperature electrode and the low temperature electrodes. The first and the second external electrode are electrically connected to one of the low temperature electrode and another one of the low temperature electrode respectively. The first external electrode and the second external electrode are disposed opposite each other with the thermoelectric conversion portion therebetween in such a manner that the centerlines of the first and second external electrodes are aligned substantially in line with each other.

### CROSS-REFERENCE TO RELATED APPLICATIONS

This application claims the benefit of priority of Japanese Patent Application No. 2006-290191, filed Oct. 25, 2006, the entire contents of which are incorporated herein by reference.

### BACKGROUND

1. Field

The present invention relates to a thermoelectric conversion module that mutually converts thermal energy and electrical energy, and to a thermoelectric conversion apparatus including the thermoelectric conversion modules connected one to another.

2. Description of the Related Art

The present invention relates to a thermoelectric conversion module that mutually converts thermal energy and electrical energy, and to a thermoelectric conversion apparatus including the thermoelectric conversion modules connected one to another.

2. Description of the Related Art

As the consumption of energy is rapidly mounting, the emission of greenhouse gases, such as CO₂, increases and causes global warming. Accordingly, a source of energy generation from which CO₂ emission can be reduced is desired.

An efficient thermoelectric conversion system for a large amount of waste heat generated from, for example, thermal power plants, such as a steam turbine electric power plant, has been put into a practical use as a source of energy generation emitting a reduced amount of CO₂. However, the efficiency of thermoelectric conversion systems for a small or medium amount of waste heat generated from small and medium plants has not reached a sufficient level in practice.

The use of a steam turbine electric power plant or the like for a small amount of waste heat leads to a quite large system in relation to the amount of waste heat and results in an extremely low power generation efficiency. Consequently, a sufficient amount of power cannot be generated in proportion to reconstruction, maintenance, and remedy costs of existing facilities.

Accordingly, thermoelectric conversion modules converting even a small or medium amount of waste heat into electrical energy receive attention as a simple and small type of thermoelectric converter.

The thermoelectric conversion module includes a thermoelectric conversion portion, a first external electrode through which current is extracted from the thermoelectric conversion portion, and a second external electrode through which current is supplied to the thermoelectric conversion portion. The thermoelectric conversion module mutually converts thermal energy and electrical energy.

The thermoelectric conversion portion includes a single thermoelectric conversion portion element or a plurality of thermoelectric conversion portion elements electrically connected to one another. The thermoelectric conversion portion element includes a high temperature electrode, low temperature electrodes, and a set of n-type thermoelectric conversion semiconductor layer and p-type thermoelectric conversion semiconductor layer disposed between the high temperature electrode and the low temperature electrode.

In the thermoelectric conversion portion element, a first low temperature electrode, the n-type thermoelectric conversion semiconductor layer, the high temperature electrode, the p-type thermoelectric conversion semiconductor layer, and a second low temperature electrode are electrically connected in that order in series. The thermoelectric conversion portion element mutually converts thermal energy and electrical energy by the Seebeck effect or the Peltier effect.

A known thermoelectric conversion module has been disclosed in, for example, a patent document Japanese Unexamined Patent Application Publication No. 2004-119833.

This thermoelectric conversion module includes a first and a second electrode respectively disposed on a first and a second insulating substrate opposing each other, and a p-type and an n-type thermoelectric element disposed between the first and the second insulating substrate. Each end of the p-type and n-type thermoelectric elements is electrically connected to the first electrode or the second electrode.

Communicating holes are formed in at least one of the first and second insulating substrates and the electrode on the insulating substrate having the hole so as to communicate with each other. Each thermoelectric element is joined with the electrodes with an end of the thermoelectric element in the communicating holes of the insulating substrate and the corresponding electrode.

Two lead wires extend in parallel in the transverse direction from one edge of the rectangular thermoelectric conversion module, and serve as means for extracting electricity from the thermoelectric conversion module at a predetermined timing (first external electrode) and means for supplying electricity to the thermoelectric conversion module at a predetermined timing (second external electrode).

In the thermoelectric conversion module of the above-cited patent document, the yield of joining between the thermoelectric element and the electrodes can be enhanced even if the insulating substrate is warped or the height of the thermoelectric element varies.

In order to generate high electrical energy from a thermoelectric conversion module, it has been proposed that the first external electrodes and the second external electrodes of a plurality of thermoelectric conversion modules are connected in series.

For connecting the thermoelectric conversion modules of the cited patent document, the first external electrode cannot be directly connected to the second external electrode.

If the thermoelectric conversion modules of the cited patent document are connected in series in the same manner as those designated by reference numeral 90 in FIG. 15, external electrode joining members 93 are additionally used to connect the first external electrodes 91 to the second external electrodes 92.

In addition, a thermoelectric conversion apparatus 80 defined by thermoelectric conversion modules 90 connected in series requires spaces, each for disposing the first external electrode 91, the second external electrode 92, and the external electrode joining member 93 the sides of each thermoelectric conversion module 90 in the direction of the line of the thermoelectric conversion modules 90.

As described above, when a plurality of thermoelectric conversion modules connected one to another are used, the thermoelectric conversion modules of the cited patent document requires additional members (external electrode joining members) for connecting the first external electrodes to the second external electrodes and spaces for disposing the first external electrode, the second external electrode, and the external electrode joining member. Consequently, this type of thermoelectric conversion module has problems in cost and space, and the power generation per installation area is undesirably low.

### SUMMARY OF THE INVENTION

The present invention has been made in light of the above situation, and accordingly it is an object of the present invention to provide a thermoelectric conversion module superior in cost and space and exhibiting a high power generation per installation area when a plurality of the thermoelectric conversion modules connected one to another is used, and to provide a thermoelectric conversion apparatus including the thermoelectric conversion modules.

To solve the above problem, a thermoelectric conversion module according to one aspect of the present invention includes a high temperature electrode, low temperature electrodes including a first low temperature electrode and a second low temperature electrode opposing the high temperature electrode and staggered with respect to the high temperature electrode in the direction parallel to the surface thereof, and a set of n-type thermoelectric conversion semiconductor layer and p-type thermoelectric conversion semiconductor layer disposed between the high temperature electrode and the low temperature electrodes. The first low temperature electrode, the n-type thermoelectric conversion semiconductor layer, the high temperature electrode, the p-type thermoelectric conversion semiconductor layer, and the second low temperature electrode are electrically connected in that order in series, thus defining the thermoelectric conversion portion element. The thermoelectric conversion module also includes a first external electrode through which current is extracted from the thermoelectric conversion portion when the high temperature electrode has a higher temperature than the low temperature electrodes, and a second external electrode through which current is supplied to the thermoelectric conversion portion when the high temperature electrode has a higher temperature than the low temperature electrode. The second external electrode is disposed opposite the first external electrode with the thermoelectric conversion portion therebetween in such a manner that the centerlines of the first and second external electrodes are aligned substantially in line with each other.

Further, to solve the above problem, a thermoelectric conversion apparatus according to another aspect of the present invention includes a plurality of the above-described thermoelectric conversion modules electrically connected in series using the first external electrodes and the second external electrodes.

### BRIEF DESCRIPTION OF THE DRAWINGS

The accompanying drawings, which are incorporated in and constitute a part of the specification, illustrate embodiments of the invention, and together with the general description given above and the detailed description of the embodiments given below, serve to explain the principles of the invention.

FIG. 1 is a perspective view of a thermoelectric conversion module according to a first embodiment of the present invention;

FIG. 2 is a perspective view of the thermoelectric conversion module shown in FIG. 1 when viewed from the rear side;

FIG. 3 is a sectional view of the thermoelectric conversion module taken along line III-III of FIG. 1;

FIG. 4 is a representation of the operation of a thermoelectric conversion portion element;

FIG. 5 is a plan view of the thermoelectric conversion modules in a use according to the first embodiment;

FIG. 6 is a plan view of the thermoelectric conversion modules in another use according to the first embodiment;

FIG. 7 is a plan view of the thermoelectric conversion modules in still another use according to the first embodiment;

FIG. 8 is a plan view of a thermoelectric conversion module according to a second embodiment of the present invention;

FIG. 9 is a bottom view of the thermoelectric conversion module according to the second embodiment;

FIG. 10 is a perspective view of a thermoelectric conversion module according to a third embodiment of the present invention;

FIG. 11 is a perspective view of a thermoelectric conversion module according to a fourth embodiment of the present invention;

FIG. 12 is a perspective view of a thermoelectric conversion module according to a fifth embodiment of the present invention;

FIG. 13 is a sectional view of a thermoelectric conversion module according to a sixth embodiment of the present invention;

FIG. 14 is a sectional view of a thermoelectric conversion module according to a seventh embodiment of the present invention; and

FIG. 15 is a plan view of known thermoelectric conversion modules in use.

### DETAILED DESCRIPTION

Hereinbelow, a description will be given of a thermoelectric conversion module and a thermoelectric conversion apparatus, according to an embodiment of the present invention with reference to the drawings.

### First Embodiment

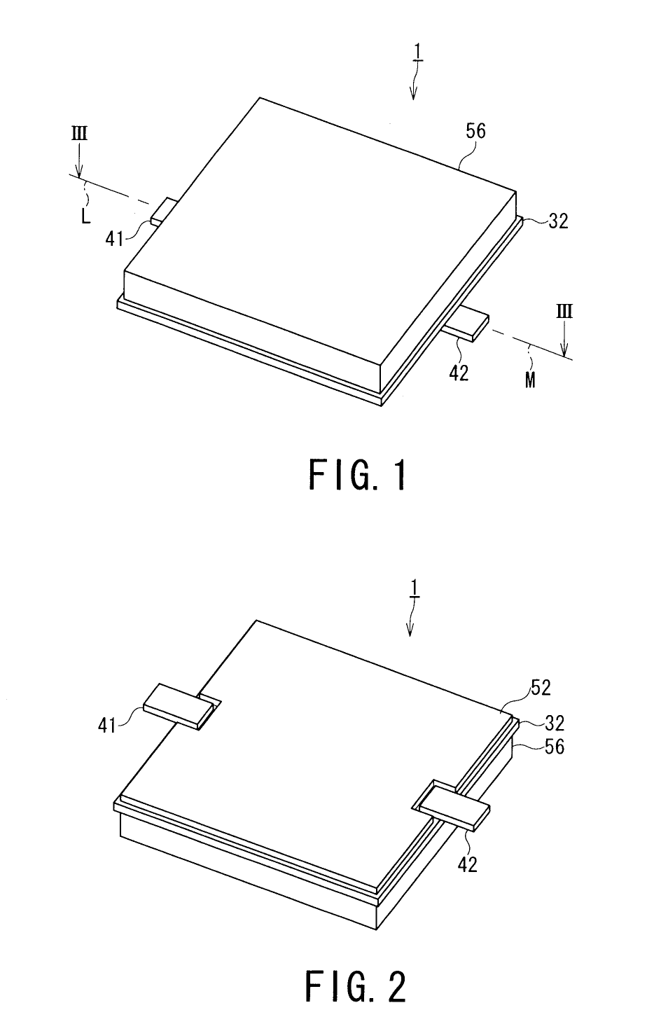

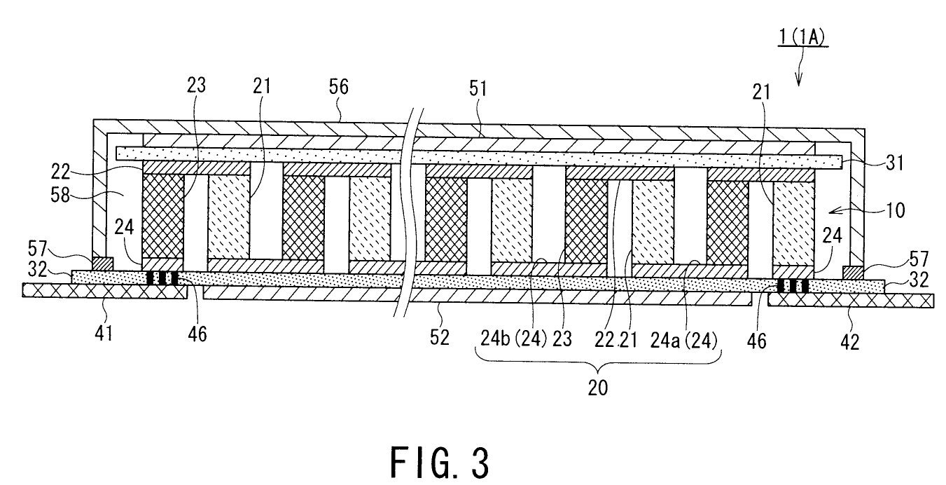

FIG. 1 is a perspective view of a thermoelectric conversion module 1 according to a first embodiment of the present invention. FIG. 2 is a perspective view of the thermoelectric conversion module 1 shown in FIG. 1 when viewed from the rear side. FIG. 3 is a sectional view of the thermoelectric conversion module 1 taken along line III-III of FIG. 1.

As shown in FIG. 1 and FIG. 2, the thermoelectric conversion module 1 includes a low temperature insulating layer 32, a casing 56 defining an enclosed housing space 58 in cooperation with the low temperature insulating layer 32, a first external electrode 41, and a second external electrode 42. A thermoelectric conversion portion 10 is housed in the housing space 58 defined by the low temperature insulating layer 32 and the casing 56.

As shown in FIG. 3, the thermoelectric conversion portion 10 includes low temperature electrodes 24 and a set of n-type thermoelectric conversion semiconductor layer 21 and p-type thermoelectric conversion semiconductor layer 23 disposed on one surfaces of the low temperature electrodes 24, and is housed in the housing space 58 with the other surfaces of the low temperature electrodes 24 bonded to the low temperature insulating layer 32. The low temperature insulating layer 32 may be, for example, a ceramic plate.

The casing 56 is bonded to the low temperature insulating layer 32 with a sealing metal layer 57 to define the housing space 58 in cooperation with the low temperature insulating layer 32.

The casing 56 is generally made of nickel, a nickel alloy, an iron alloy, a chromium-containing iron alloy, a silicon-containing iron alloy, a cobalt-containing iron alloy, or a copper alloy. These metals are not easily corroded by an inert gas that may fill the housing space 58, and are thus suitable as the material of the casing 56.

The thermoelectric conversion portion 10 is defined by a single thermoelectric conversion portion element 20, or electrically connected thermoelectric conversion portion elements 20. The thermoelectric conversion portion elements 20 are generally connected in series, but may be electrically connected in parallel. The thermoelectric conversion portion 10 may defined by thermoelectric conversion portion elements 20 electrically connected in parallel or a single thermoelectric conversion portion element 20.

The thermoelectric conversion portion element 20 includes a high temperature electrode 22, low temperature electrodes 24 opposing the high temperature electrode 22, staggered in the direction parallel to the surface of the high temperature electrode 22, and a pair of n-type thermoelectric conversion semiconductor layer 21 and p-type thermoelectric conversion semiconductor layer 23 disposed between the high temperature electrode 22 and the low temperature electrodes 24.

The n-type thermoelectric conversion semiconductor layer 21 and the p-type thermoelectric conversion semiconductor layer 23 are each arranged in such a manner that their one ends are in contact with the same surface of the high temperature electrode 22. The other ends of the n-type thermoelectric conversion semiconductor layer 21 and the p-type thermoelectric conversion semiconductor layer 23 are in contact with different electrically isolated low temperature electrodes 24: first low temperature electrode 24a and second low temperature electrode 24b.

Hence, the thermoelectric conversion portion element 20 has a structure in which the first low temperature electrode 24a, the n-type thermoelectric conversion semiconductor layer 21, the high temperature electrode 22, the p-type thermoelectric conversion semiconductor layer 23, and the second low temperature electrode 24b are electrically connected in that order in series.

The high temperature electrode 22 refers to the electrode located at the high temperature side of the thermoelectric conversion portion element 20. The high temperature electrode 22 can be made of a known electrode material, such as a copper foil or a copper plate.

The low temperature electrodes 24 refer to the electrodes located at the low temperature side of the thermoelectric conversion portion element 20. The low temperature electrodes 24 can also be made of a known electrode material, such as a copper foil or a copper plate.

The first low temperature electrode 24a is connected to the n-type thermoelectric conversion semiconductor layer 21, and the second low temperature electrode 24b is connected to the p-type thermoelectric conversion semiconductor layer 23.

The low temperature electrode 24 can be formed by, for example, bonding a low temperature electrode 24 material to the entire surface of the low temperature insulating layer 32 and then etching it.

The thermoelectric conversion portion 10 also includes a high temperature insulating layer 32 and is enclosed in such a manner that the surface of the high temperature electrode 22 opposite the surface in contact with the n-type and p-type thermoelectric conversion semiconductor layers 21 and 23 is bonded to the high temperature insulating layer 31. The high temperature insulating layer 31 may be, for example, a ceramic plate.

The p-type thermoelectric conversion semiconductor layer 23 is made of a known p-type thermoelectric conversion semiconductor having a high performance index, and the n-type thermoelectric conversion semiconductor layer 21 is made of a known n-type thermoelectric conversion semiconductor having a high performance index.

Thermoelectric semiconductors having high performance indices include materials having a main phase formed of a compound containing bismuth and tellurium, materials having a main phase formed of a compound containing bismuth and selenium, materials having a main phase formed of a compound containing bismuth and antimony, materials having a main phase formed of a filled skutterudite CoSb₃ compound having voids filled with atoms, materials having a main phase formed of a half-Heusler MgAgAs compound, clathrate compounds containing barium and gallium as guest atoms, and mixtures or composites of these materials and compounds. A p-type and an n-type thermoelectric conversion semiconductor layer made of such thermoelectric materials advantageously exhibit high thermoelectric conversion efficiency.

The p-type thermoelectric conversion semiconductor layer 23 and the n-type thermoelectric conversion semiconductor layer 21 are generally in a cylindrical, rectangular solid, or polygonal solid shape and their bottoms and tops are bonded to the high temperature electrode 22 and the low temperature electrode 24, respectively.

A high temperature metal plate 51 is disposed between the high temperature insulating layer 31 of the thermoelectric conversion portion 10 and the casing 56. The high temperature metal plate 51 is generally made of nickel, a nickel alloy, an iron alloy, chromium-containing iron alloy, a silicon-containing iron alloy, a cobalt-containing iron alloy, or a copper alloy. These materials are not easily corroded by an inert gas that may fill the housing space 58, and are thus suitable as the material of the high temperature metal plate 51.

The enclosed housing space 58 defined by the low temperature insulating layer 32 and the casing 56 is generally in a vacuum state or filled with an inert gas. The housing space 58 in a vacuum state or filled with an inert gas prevents the oxidation at high temperature of the components of the thermoelectric conversion portion 10, such as the n-type thermoelectric conversion semiconductor layer 21, the p-type thermoelectric conversion semiconductor layer 23, the high temperature electrode 22, and the low temperature electrodes 24.

When a vacuum is created in the housing space 58, the vacuum state in the housing space 58 is not necessarily high, and the housing space 58 may be in such a state that can be established by, for example, a known vacuum pump.

The inert gas filling the housing space 58 is generally at least one selected from the group consisting of nitrogen, helium, neon, argon, krypton, and xenon.

The pressure of the inert gas filling the housing space 58 is set lower than the outside pressure at 25° C.; otherwise, the temperature of the housing space 58 is increased to several hundred degrees, for example, about 800° C., during operation of the thermoelectric conversion module and, accordingly, the pressure of the inert gas is increased. By setting the inert gas pressure lower than the outside pressure at 25° C., problems resulting from the increase of the inert gas pressure can be prevented. For example, the thermoelectric conversion portion 10 can be prevented from being broken, or the inert gas can be prevented from leaking from the housing space 58 and thus the air-tight condition of the housing space 58 can be prevented from being degraded.

A low temperature metal plate 52 is bonded to the external surface of the low temperature insulating layer 32, that is, to the surface of the low temperature insulating layer 32 opposite the surface on which the thermoelectric conversion module 1 is disposed. The low temperature metal plate 52 is generally made of nickel, a nickel alloy, an iron alloy, a chromium-containing iron alloy, a silicon-containing iron alloy, a cobalt-containing iron alloy, or a copper alloy.

The thermoelectric conversion module 1 includes a first external electrode 41 and a second external electrode 42. When the high temperature electrode 22 has a higher temperature than the low temperature electrode 24, current is extracted from the thermoelectric conversion portion 10 through the first external electrode 41 and is supplied to the thermoelectric conversion portion 10 through the second external electrode. A known electroconductive metal plate, such as a copper plate or a copper nickel alloy plate, can be used as the first external electrode 41 and the second external electrode 42.

When the thermoelectric conversion module 1 is used to convert heat into electricity under the general condition that the high temperature electrode 22 has a higher temperature than the low temperature electrode 24, the first external electrode 24 is positive and the second external electrode 42 is negative.

On the other hand, when the thermoelectric conversion module 1 is used to convert heat into electricity under the condition that the high temperature electrode 22 has a lower temperature than the low temperature electrode 24, the first external electrode 41 is negative and the second external electrode 42 is positive.

The first external electrode 41 and the second external electrode 42 are each electrically connected to the low temperature electrodes 24 through a current extraction portion 46 running across the low temperature insulating layer 32. The current extraction portion 46 is a filled via hole defined by a hole formed in the low temperature insulating layer 32 and filled with an electroconductive material, such as silver powder or copper powder.

As shown in FIG. 1, the first external electrode 41 and the second external electrode 42 are disposed opposite each other with the thermoelectric conversion portion 10 therebetween in the casing 56 and are extended to opposite directions to each other substantially from the center of opposing two edges of the rectangular low temperature insulating layer 32. The first external electrode 41 and the second external electrode 42 are disposed in such a manner that the centerline (designated by L in FIG. 1) of the first external electrode 41 is aligned substantially in line with the centerline (designated by M in FIG. 1) of the second external electrode 42.

Note that with the present embodiment, the centerlines are lines representing the centers in the width direction of the first external electrode 41 and the second external electrode 42.

As shown in FIG. 2, the first external electrode 41 and the second external electrode 42 are disposed on the external surface of the low temperature insulating layer 32, that is, to the surface of the low temperature insulating layer 32 opposite the surface on which the low temperature electrodes 24 are disposed.

The first external electrode 41 and the second external electrode 42 are rectangular electroconductive metal plates protruding from the external surface of the low temperature insulating layer 32 of the thermoelectric conversion portion 10.

The first external electrode 41 and the second external electrode 42 may be covered with a heat-resistant inorganic material containing at least one ceramic selected from the group consisting of alumina, silicon nitride, aluminium nitride, zirconia, yttria, silica, and beryllia, or a ceramic compound containing such ceramic. Consequently, first external electrode 41 and the second external electrode 42 can advantageously exhibit heat resistance even if the thermoelectric conversion module 1 is used at a high temperature of, for example, about 800° C.

Preferably, alumina or silica is present in form of powder or fiber in the heat-resistant inorganic material from the viewpoint of enhancing the heat resistance of the heat-resistant inorganic material.

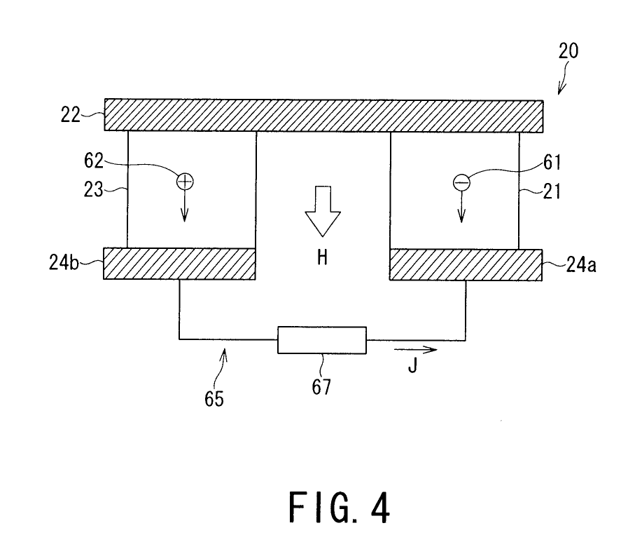

The operation of the thermoelectric conversion module 1 will now be described with reference to FIG. 4. FIG. 4 is a representation illustrating the operation of the thermoelectric conversion portion element 10.

In the thermoelectric conversion module 1, when the high temperature electrode 22 has a higher temperature than the low temperature electrode 24 and a heat flow occurs in the direction indicated by arrow H, electrons 61 in the n-type thermoelectric conversion semiconductor layer 21 transfer to the first low temperature electrode 24a side from the high temperature electrode 22 side, as shown in FIG. 4.

At the same time, holes 62 in the p-type thermoelectric conversion semiconductor layer 23 transfer to the second low temperature electrode 24b side from the high temperature electrode 22 side, as shown in FIG. 4.

In this situation, therefore, when an external circuit 65 including an electrical load 67 is disposed between the first low temperature electrode 24a and the second low temperature electrode 24b, current flows in the direction indicated by arrow J shown in FIG. 4 in the thermoelectric conversion portion element 20 of the thermoelectric conversion portion 10.

As shown in FIG. 3, in the thermoelectric conversion module 1, the first external electrode 41 is disposed between one of the low temperature electrodes 24, which is electrically connected to the p-type thermoelectric conversion semiconductor layer 23, and the electrical load 67. And the second external electrode 42 is disposed between another one of the low temperature electrodes 24, which is electrically connected to the n-type thermoelectric conversion semiconductor layer 21, and the electrical load 67. Consequently, current is extracted through the first external electrode 41 and supplied to the second external electrode 42. Thus, the thermoelectric conversion module 1 can covert thermal energy to electrical energy.

When, in thermoelectric conversion module 1, the high temperature electrode 22 has a lower temperature than the low temperature electrode 24, current flows in the direction opposite to the direction of arrow J. In this instance, current is supplied to the first external electrode 41 and extracted through the second external electrode 42.

When a current is applied to the thermoelectric conversion module 1 with the external circuit 65 so as to flow from the first low temperature electrode 24a of the thermoelectric conversion portion element 20 to the second low temperature electrode 24b through the high temperature electrode 22, the high temperature electrode 22 absorbs heat to cool the surroundings, and the first low temperature electrode 24a and the second low temperature electrode 24b release heat to heat the surroundings. Thus, the thermoelectric conversion module 1 can convert electrical energy to thermal energy.

When a current is applied to the thermoelectric conversion module 1 with the external circuit 65 so as to flow to the first low temperature electrode 24a from the second low temperature electrode 24b through the high temperature electrode 22, the first low temperature electrode 24a and the second low temperature electrode 24b absorb heat to cool the surroundings, and the high temperature electrode 22 releases heat to heat the surroundings.

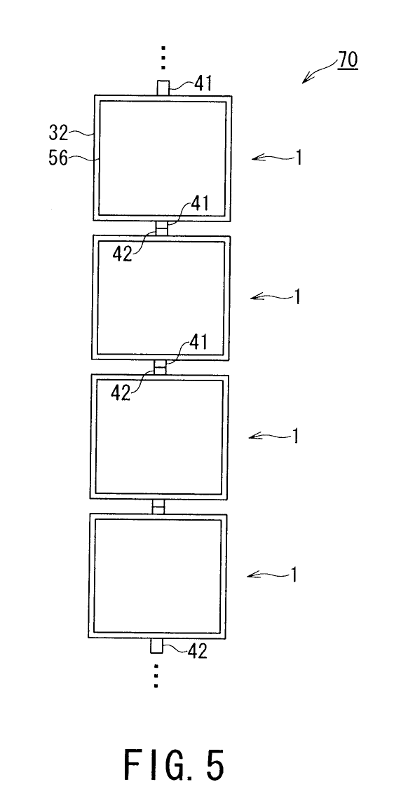

The thermoelectric conversion modules 1 may be arranged in such a manner that each two adjacent thermoelectric conversion modules are connected in series using the first external electrodes 41 and the second external electrodes 42, as shown in FIG. 5, thus defining a thermoelectric conversion apparatus 70. Hence, the thermoelectric conversion apparatus 70 is produced by electrically connecting the thermoelectric conversion modules 1 in series in line.

The connection between the first external electrode 41 and the second external electrode 42 of two adjacent thermoelectric conversion modules 1 may be established by soldering, or by using a set of bolt and nut for holes formed in the first external electrode 41 and the second external electrode 42.

The thermoelectric conversion apparatus 70 can provide higher electrical energy, particularly higher voltage, than the thermoelectric conversion module 1.

Since in the thermoelectric conversion apparatus 70, each two adjacent thermoelectric conversion modules 1 are directly connected to each other using the first external electrode 41 and the second external electrode 42 that are disposed with their centerlines substantially aligned in line, it is not necessary to provide external electrode joining members 47 between the first external electrodes 41 and the second external electrodes 42. Thus, the resulting thermoelectric conversion apparatus can be superior in cost and space, and can exhibit higher power generation per installation space.

A thermoelectric conversion module 1 including a plurality of thermoelectric conversion modules 1 connected one to another can be superior in cost and space and can exhibit an increased power generation per installation area.

The thermoelectric conversion module 1 can also prevent the oxidation at high temperature of the components of the thermoelectric conversion portion 10, such as the n-type thermoelectric conversion semiconductor layer 21, the p-type thermoelectric conversion semiconductor layer 23, the high temperature electrode 22, and the low temperature electrodes 24.

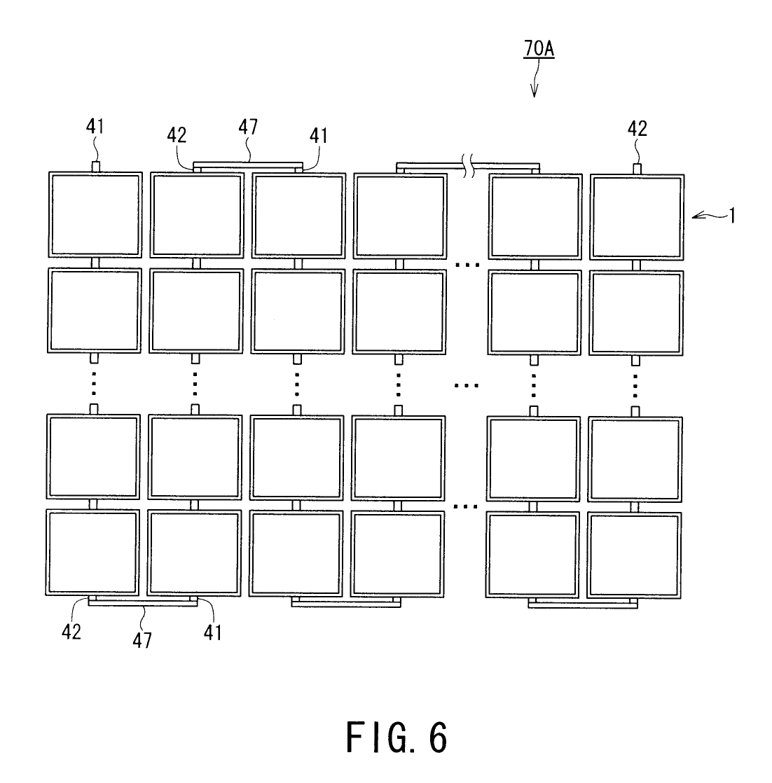

The thermoelectric conversion modules 1 may be connected as shown in FIG. 6 to define a thermoelectric conversion apparatus 70A. More specifically, the thermoelectric conversion apparatus 70A includes straight portions defined by electrically connecting thermoelectric conversion modules 1 in series in line and curved portions defined by turning back the line of the thermoelectric conversion modules 1 electrically connected in series.

The connection between the straight portion and the curved portion of the thermoelectric conversion modules 1 is established using an external electrode joining member 47 between the first external electrodes 41 and the second external electrodes 42.

The external electrode joining member 47 may be a known electroconductive metal plate, such as a copper plate or a copper nickel alloy plate, as with the first external electrode 41 and the second external electrode 42.

The external electrode joining member 47 may be covered with a heat-resistant inorganic material containing at least one ceramic selected from the group consisting of alumina, silicon nitride, aluminium nitride, zirconia, yttria, silica, and beryllia, or a ceramic compound containing such ceramic, as with the first external electrode 41 and the second external electrode 42. Consequently, the external electrode joining member 47 can advantageously exhibit heat resistance even if the thermoelectric conversion apparatus 70A are used at a high temperature of, for example, about 800° C.

Preferably, alumina or silica is present in form of powder or fiber in the heat-resistant inorganic material from the viewpoint of enhancing the heat resistance of the heat-resistant inorganic material.

The thermoelectric conversion apparatus 70A can provide higher electrical energy, particularly higher voltage, than the thermoelectric conversion module 1.

The thermoelectric conversion apparatus 70A allows an efficient two-dimensional arrangement of the thermoelectric conversion modules 1 electrically connected in series, as well as producing the same effect as the thermoelectric conversion apparatus 70. Thus, the resulting thermoelectric conversion apparatus can be superior in cost and space, and can exhibit still higher power generation per installation area.

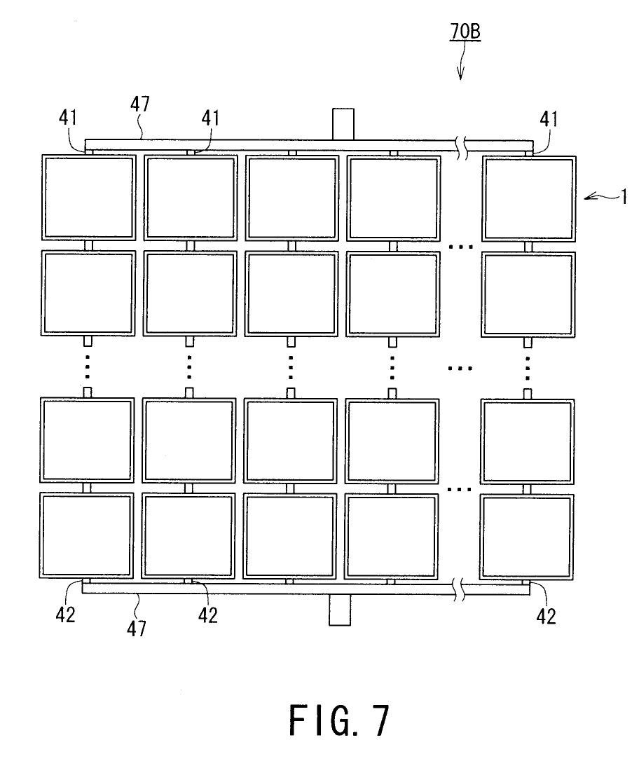

The thermoelectric conversion modules 1 may be arranged as shown in FIG. 7 to define a thermoelectric conversion apparatus 70B. More specifically, the thermoelectric conversion apparatus 70B is produced by connecting straight lines of the thermoelectric conversion modules 1 electrically connected in series, in parallel with each other.

The external electrode joining members 47 used in the thermoelectric conversion apparatus 70B are made of the same material as those used in the thermoelectric conversion apparatus 70A.

The thermoelectric conversion apparatus 70B can provide still higher electrical energy, particularly higher voltage, than the thermoelectric conversion module 1 over a long term.

The thermoelectric conversion apparatus 70B allows an efficient two-dimensional arrangement of the thermoelectric conversion modules 1 electrically connected in series and can provide electrical energy over a long term, as well as producing the same effect as the thermoelectric conversion apparatus 70. Thus, the resulting thermoelectric conversion apparatus can be superior in cost and space and can exhibit still higher power generation per installation area.

### Second Embodiment

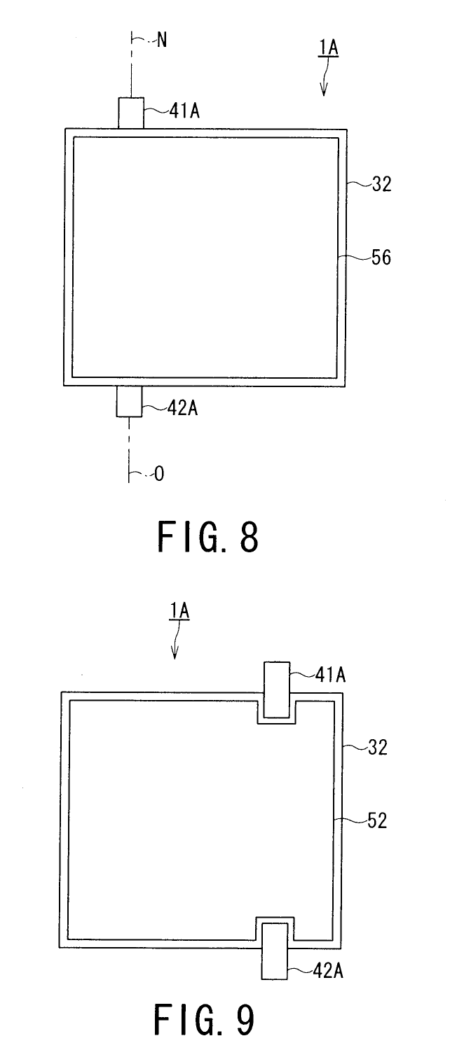

A thermoelectric conversion module according to a second embodiment of the present invention will now be described with reference to FIGS. 8 and 9.

The thermoelectric conversion module 1A according to the second embodiment has the same structure as the thermoelectric conversion module 1 of the first embodiment, except that a first external electrode 41A and a second external electrode 42A are used instead of the first external electrode 41 and the second external electrode 42. The same parts in the drawings are designated by the same reference numerals, and the descriptions of the same parts will be simplified or omitted.

FIG. 8 is a plan view of the thermoelectric conversion module 1A according to the second embodiment of the present invention, and FIG. 9 is a bottom view of the thermoelectric conversion module 1A.

The first external electrode 41A and second external electrode 42A of the thermoelectric conversion module 1A are disposed with the thermoelectric conversion portion 10 in the casing 56 therebetween, and protrude from positions shifted from the centers of two opposing sides of the rectangular low temperature insulating layer 32 toward one ends of the two sides.

In addition, the centerline (designated by N in FIG. 8) of the first external electrode 41A is aligned substantially in line with the centerline (designated by 0 in FIG. 8) of the second external electrode 42A.

The first external electrode 41A and the second external electrode 42A are the same as the first external electrode 41 and second external electrode 42 of the thermoelectric conversion module 1 except for where they are disposed on the low temperature insulating layer 32, and the same descriptions will not be repeated.

The thermoelectric conversion module 1A produces the same effect as the thermoelectric conversion module 1 of the first embodiment.

The thermoelectric conversion modules 1A may be electrically connected in series using the first external electrodes 41A and the second external electrodes 42A, thus defining a thermoelectric conversion apparatus.

The thermoelectric conversion apparatus constituted of the thermoelectric conversion modules 1A has the same structure as any one of the thermoelectric conversion apparatuses 70, 70A, and 70B using the thermoelectric conversion modules 1, except that the thermoelectric conversion modules 1 are replaced with the thermoelectric conversion modules 1A, and the description of the structure and the operation will not be repeated.

### Third Embodiment

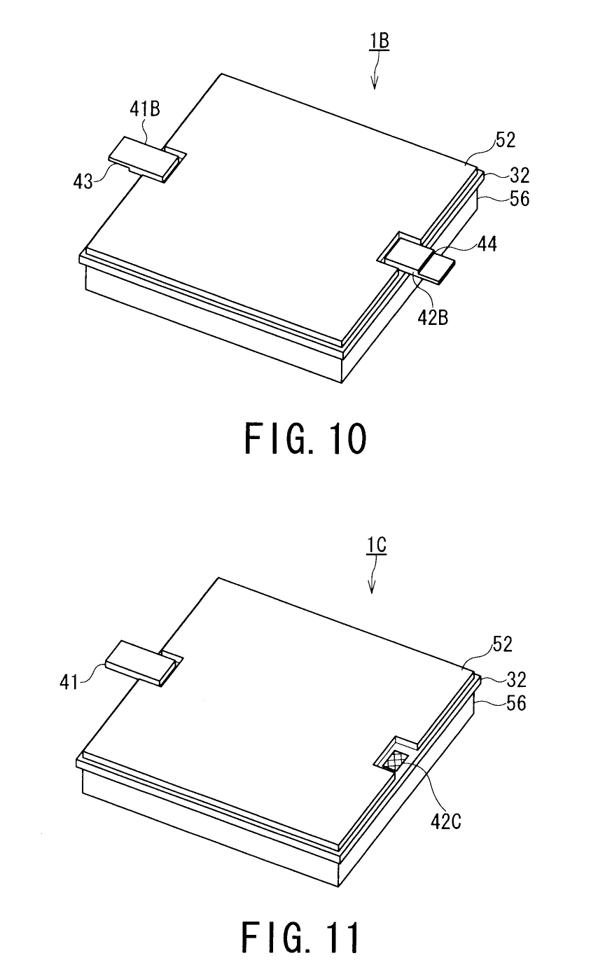

A thermoelectric conversion module according to a third embodiment of the present invention will now be described with reference to FIG. 10.

The thermoelectric conversion module 1B of the third embodiment has the same structure as the thermoelectric conversion module 1 of the first embodiment, except that a first external electrode 41B and a second external electrode 2B are used instead of the first external electrode 41 and the second external electrode 42. The same parts in the figure are designated by the same reference numerals, and the descriptions of the same parts will be simplified or omitted.

FIG. 10 is a perspective view of the thermoelectric conversion module 1B according to the third embodiment of the present invention.

The first external electrode 41B and second external electrode 42B of the thermoelectric conversion module 1B are made of the same electroconductive metal plate as the first external electrode 41 and second external electrode 42 of the thermoelectric conversion module 1 of the first embodiment, and have joining portions 43 and 44, respectively, at the ends thereof so as to be joined flush with each other.

The joining portions 43 and 44 are formed by cutting off rectangular solids with the same size and shape from the ends of the first external electrode 41B and second external electrode 42B. The joining portions 43 and 44 may have a so-called shiplap structure.

However, the joining portions are not limited to such a shiplap formed by cutting off a rectangular solid, and may be in any shape as long as the first external electrode 41B and second external electrode 42B can be joined flush with each other.

The first external electrode 41B and the second external electrode 42B are the same as the first external electrode 41 and second external electrode 42 of the thermoelectric conversion module 1 according to the first embodiment, except that the joining portions 43 and 44 are formed, and the same descriptions will not be repeated.

The thermoelectric conversion module 1B produces the same effect as the thermoelectric conversion module 1 of the first embodiment. In addition, the joining portions of the first external electrode 41B and the second external electrode 42B facilitate the reliable joining of a plurality of thermoelectric conversion modules 1B with reduced spaces for joining the first external electrodes 41B and the second external electrodes 42B.

The thermoelectric conversion modules 1B may be connected in series using the first external electrodes 41B and the second external electrodes 42B, thus defining a thermoelectric conversion apparatus.

The thermoelectric conversion apparatus constituted of the thermoelectric conversion modules 1B has the same structure as any one of the thermoelectric conversion apparatuses 70, 70A, and 70B using the thermoelectric conversion modules 1, except that the thermoelectric conversion modules 1 are replaced with the thermoelectric conversion modules 1B, and the description of the structure and the operation will not be repeated.

### Fourth Embodiment

A thermoelectric conversion module according to a fourth embodiment of the present invention will now be described with reference to FIG. 11.

The thermoelectric conversion module 1C according to the fourth embodiment of the present invention has the same structure as the thermoelectric conversion module 1 of the first embodiment, except that another type of second external electrode 42C is used instead of the second external electrode 42. The same parts in the figure are designated by the same reference numerals, and the description of the same parts will be simplified or omitted.

The second external electrode 42C is defined by a metal film formed on the external surface of the low temperature insulating layer 32. The surface of the second external electrode 42C is brought into contact with the surface of the tip of the first external electrode 41.

The thermoelectric conversion module 1C produces the same effect as the thermoelectric conversion module 1 of the first embodiment. In addition, the different type of second external electrode 42C facilitates the reliable joining of a plurality of thermoelectric conversion modules 1C with reduced spaces for joining the first external electrodes 41 and the second external electrodes 42C.

The thermoelectric conversion modules 1C may be connected in series using the first external electrodes 41 and the second external electrodes 42C, thus defining a thermoelectric conversion apparatus.

The thermoelectric conversion apparatus constituted of the thermoelectric conversion modules 1C has the same structure as any one of the thermoelectric conversion apparatuses 70, 70A, and 70B using the thermoelectric conversion modules 1, except that the thermoelectric conversion modules 1 are replaced with the thermoelectric conversion modules 1C, and the description of the structure and the operation will not be repeated.

### Fifth Embodiment

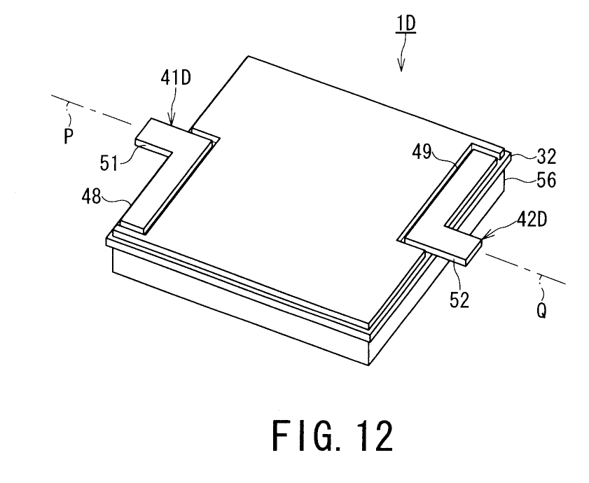

A thermoelectric conversion module according to a fifth embodiment of the present invention will now be described with reference to FIG. 12.

The thermoelectric conversion module 1D according to the fifth embodiment of the present invention has the same structure as the thermoelectric conversion module 1 of the first embodiment, except that a first external electrode 41D and a second external electrode 42D are used instead of the first external electrode 41 and the second external electrode 42. The same parts in the figure are designated by the same reference numerals, and the description of the same parts will be simplified or omitted.

FIG. 12 is a perspective view of the thermoelectric conversion module 1D of the fifth embodiment.

The first external electrode 41D and second external electrode 42D of the thermoelectric conversion module 1D are each an L-shaped electroconductive metal plate including a rectangular base portion 48 or 49 and a rectangular protruding portion 51 or 52. The protruding portions 51 and 52 have a rectangular shape having a length equal to the entire length in the protruding direction of the L-shaped metal electrode and a width equal to the width of the protruding portion. The base portions 48 and 49 are the portions of the L-shaped metal electrodes other than the protruding portions 51 and 52, respectively.

The first external electrode 41D and the second external electrode 42D are combined so that the centerline (designated by P in FIG. 12) of the protruding portion 51 of the L-shaped electroconductive metal plate acting as the first external electrode 41 is aligned substantially in line with the centerline (designated by Q in FIG. 12) of the protruding portion 52 of the L-shaped electroconductive metal plate acting as the second external electrode 42.

The current extraction portions 46 running across the low temperature insulating layer 32 and electrically connected to the low temperature electrodes 24 are connected to the straight base portions 48 and 49 of the first external electrode 41D and the second external electrode 42D, respectively.

Consequently, the current extraction portions 46 do not appear at the section of the thermoelectric conversion module 1D taken along a line joining the centerlines P and Q of the protruding portions 51 and 52, unlike the current extraction portions 46 of the thermoelectric conversion module 1 as shown in FIG. 3. The sectional view of the thermoelectric conversion module 1D is omitted.

The first external electrode 41D and the second external electrode 42D are the same as the first external electrode 41 and second external electrode 42 of the thermoelectric conversion module 1 of the first embodiment, except for being in an L shape, and the descriptions will not be repeated.

The thermoelectric conversion module 1D produces the same effect as the thermoelectric conversion module 1 of the first embodiment. In addition, since the electrical connection of the first external electrode 41D and second external electrode 42D to the low temperature electrodes 24 is established with the current extraction portions connected to the base portions 48 and 49, the flexibility of arrangement of the thermoelectric conversion portion elements 20 constituting the thermoelectric conversion portion 10 can be dramatically increased.

In the thermoelectric conversion module 1D of the fifth embodiment, the low temperature electrode 24 connected to the first external electrode 41D through the current extraction portion and the low temperature electrode 24 connected to the second external electrode 42D through the current extraction portion can be disposed not only around the centers of two opposing sides of the rectangular low temperature insulating layer 32, but also at corners in the direction of a diagonal line of the low temperature insulating layer 32 or at two adjacent corners, that is, at both ends of a side of the low temperature insulating layer 32.

The thermoelectric conversion modules 1D may be connected in series using the first external electrodes 41D and the second external electrodes 42D, thus defining a thermoelectric conversion apparatus.

The thermoelectric conversion apparatus constituted of the thermoelectric conversion modules 1D has the same structure as any one of the thermoelectric conversion apparatuses 70, 70A, and 70B using the thermoelectric conversion modules 1, except that the thermoelectric conversion modules 1 are replaced with the thermoelectric conversion modules 1D, and the description of the structure and the operation will not be repeated.

The protruding portions 51 and 52 of the first external electrode 41D and second external electrode 42D of the thermoelectric conversion module 1D may be disposed at the same positions as the first external electrode 41A and second external electrode 42A of the thermoelectric conversion module 1A of the second embodiment. In this instance, the base portions 48 and 49 of the first external electrode 41D and the second external electrode 42D may be formed at an appropriate length.

The protruding portions 51 and 52 of the first external electrode 41D and second external electrode 42D of the thermoelectric conversion module 1D may have joining portions similar to the joining portions 43 and 44 of the first external electrode 41B and second external electrode 42B of the thermoelectric conversion module 1B in the third embodiment.

One of the first external electrode 41D and second external electrode 42D of the thermoelectric conversion module 1D may be defined by a metal film like the second external electrode 42C of the thermoelectric conversion module 1C of the fourth embodiment.

### Sixth Embodiment

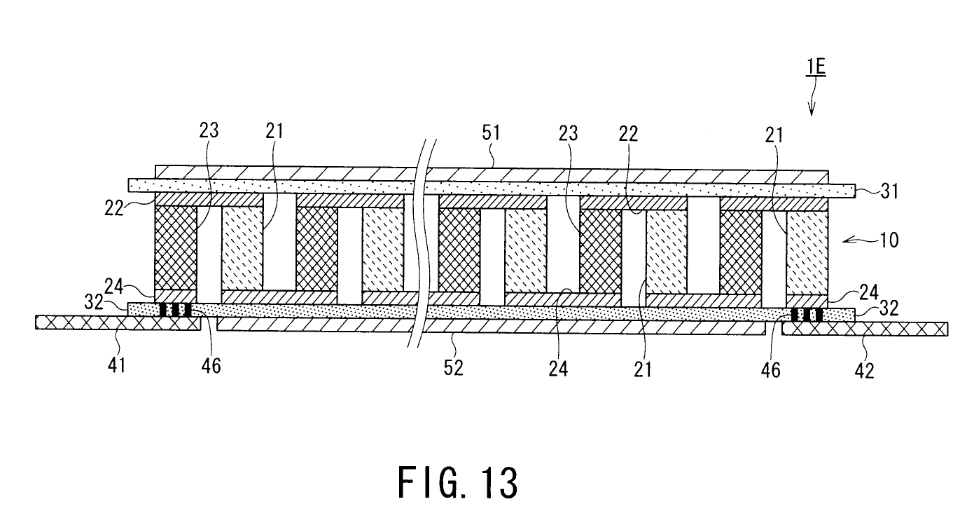

A thermoelectric conversion module according to a sixth embodiment of the present invention will now be described with reference to FIG. 13.

The thermoelectric conversion module 1E of the sixth embodiment has the same structure as the thermoelectric conversion module 1 of the first embodiment, but the casing 56 is not used.

The thermoelectric conversion module 1E produces the same effect as the thermoelectric conversion module 1 of the first embodiment. In addition, since the casing 56 is not used, the resulting thermoelectric conversion module can be more inexpensive and lighter than the thermoelectric conversion module 1 of the first embodiment.

Since the thermoelectric conversion module 1E does not have the casing 56, it cannot be placed singly in a vacuum sate or in an inert gas atmosphere. However, taking a heat source into account, the thermoelectric conversion module 1E or the thermoelectric conversion apparatuses 70 can be placed in an additional casing (not shown) in a vacuum state or in an inert gas atmosphere so that the components of the thermoelectric conversion portion 10, such as the n-type thermoelectric conversion semiconductor layer 21, the p-type thermoelectric conversion semiconductor layer 23, the high temperature electrode 22, and the low temperature electrodes 24, can be prevented from oxidizing at high temperatures, as in the thermoelectric conversion module 1.

### Seventh Embodiment

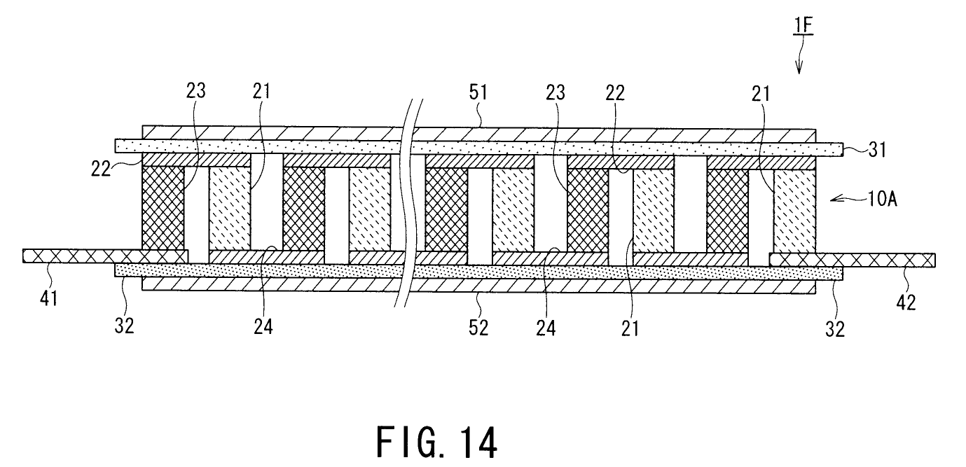

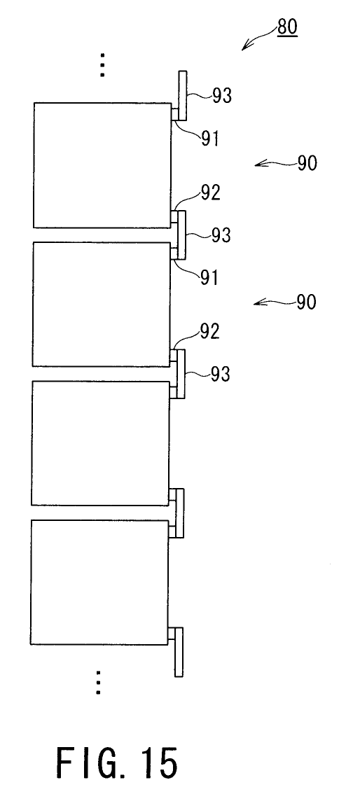

A thermoelectric conversion module according to a seventh embodiment of the present invention will now be described with reference to FIG. 14.

The thermoelectric conversion module 1F of the seventh embodiment also does not have the casing 56 of the thermoelectric conversion module 1 of the first embodiment. In addition, the first external electrode 41 is disposed between the outermost p-type thermoelectric conversion semiconductor layer 23 and the low temperature insulating layer 32, and the second external electrode 42 is disposed between the outermost n-type thermoelectric conversion semiconductor layer 21 and the low temperature insulating layer 32 without providing the current extraction portions 46.

The thermoelectric conversion module 1F produces the same effect as the thermoelectric conversion module 1 of the first embodiment. In addition, since the casing 56 are not provided, the resulting thermoelectric conversion module can be more inexpensive and lighter than the thermoelectric conversion module 1 of the first embodiment.

In the thermoelectric conversion module 1F, the first external electrode 41 and the second external electrode 42 are not disposed on the external surface of the low temperature insulating layer 32, but protrude from the positions between the low temperature insulating layer 32 and the high temperature insulating layer 31. Accordingly, when a plurality of the thermoelectric conversion modules 1F are connected, joining spaces for connecting the first external electrode 41 and the second external electrode 42 can be readily ensured.

Since the thermoelectric conversion module 1F does not have the casing 56, it cannot be placed singly in a vacuum state or in an inert gas atmosphere. However, taking a heat source into account, the thermoelectric conversion module 1F or the thermoelectric conversion apparatuses 70 can be placed in an additional casing (not shown) in a vacuum state or in an inert gas atmosphere so that the components of the thermoelectric conversion portion 10, such as the n-type thermoelectric conversion semiconductor layer 21, the p-type thermoelectric conversion semiconductor layer 23, the high temperature electrode 22, and the low temperature electrodes 24, can be prevented from oxidizing at high temperatures, as in the thermoelectric conversion module 1.

What is claimed is:

1. A thermoelectric conversion module comprising:
a thermoelectric conversion portion including a single thermoelectric conversion portion element or electrically connected thermoelectric conversion portion elements, the thermoelectric conversion portion element including a high temperature electrode, low temperature electrodes including a first low temperature electrode and a second low temperature electrode opposing the high temperature electrode and staggered with respect to the high temperature electrode in the direction parallel to the surface thereof, and a set of n-type thermoelectric conversion semiconductor layer and p-type thermoelectric conversion semiconductor layer disposed between the high temperature electrode and the low temperature electrodes, wherein the first low temperature electrode, the n-type thermoelectric conversion semiconductor layer, the high temperature electrode, the p-type thermoelectric conversion semiconductor layer, and the second low temperature electrode are electrically connected in that order in series to define the thermoelectric conversion portion element;
a first external electrode through which current is extracted from the thermoelectric conversion portion when the high temperature electrode has a higher temperature than the low temperature electrodes; and
a second external electrode through which current is supplied to the thermoelectric conversion portion when the high temperature electrode has a higher temperature than the low temperature electrode, the second external electrode being disposed opposite the first external electrode with the thermoelectric conversion portion therebetween in such a manner that the centerlines of the first and second external electrodes are aligned substantially in line with each other.

2. The thermoelectric conversion module according to claim 1, further comprising a low temperature insulating layer bonded to the surfaces of the low temperature electrodes opposite the surfaces having the n-type thermoelectric conversion semiconductor layer and p-type thermoelectric conversion semiconductor layer, wherein the first external electrode and the second external electrode are disposed on the external surface of the low temperature insulating layer.

3. The thermoelectric conversion module according to claim 2, further comprising a casing defining an enclosed housing space in cooperation with the low temperature insulating layer, wherein the thermoelectric conversion portion is housed in the housing space and the housing space is in a vacuum state or filled with an inert gas.

4. The thermoelectric conversion module according to claim 2, wherein the first external electrode and the second external electrode are each an electroconductive metal plate protruding from the external surface of the low temperature insulating layer.

5. The thermoelectric conversion module according to claim 1, wherein the first external electrode and the second external electrode are each a rectangular electroconductive metal plate protruding from the thermoelectric conversion portion.

6. The thermoelectric conversion module according to claim 4, wherein the electroconductive metal plate is in an L shape having a protruding portion, and the first external electrode and the second external electrode are disposed in such a manner that the centerlines of the protruding portions of the L shapes are aligned substantially in line with each other.

7. The thermoelectric conversion module according to claim 2, wherein one of the first external electrode and the second external electrode is an electroconductive metal plate protruding from the external surface of the low temperature insulating layer, and the other is a metal film formed on the external surface of the low temperature insulating layer, and wherein the electroconductive metal plate of the thermoelectric conversion module and the metal film of another thermoelectric conversion module having the same structure can be brought into surface contact with each other.

8. The thermoelectric conversion module according to claim 7, wherein the electroconductive metal plate is in a rectangular shape.

9. The thermoelectric conversion module according to claim 7, wherein the electroconductive metal plate is in an L shape having a protruding portion, and the centerline of the protruding portion of the L-shaped electroconductive metal plate is aligned substantially in line with the centerline of the metal film.

10. The thermoelectric conversion module according to claim 4, wherein the first external electrode can be joined with the second external electrode of another thermoelectric conversion module having the same structure so as to be flush with each other.

11. The thermoelectric conversion module according to claim 1, wherein the first external electrode and the second external electrode are covered with a heat-resistant inorganic material composed of at least one ceramic material selected from the group consisting of alumina, silicon nitride, aluminium nitride, zirconia, yttria, silica, and beryllia.

12. The thermoelectric conversion module according to claim 11, wherein the alumina and the silica are powder.

13. The thermoelectric conversion module according to claim 11, wherein the alumina and the silica are fiber.

14. A thermoelectric conversion apparatus comprising:
a plurality of thermoelectric conversion modules as set forth in any one of claims 1 to 13, the thermoelectric conversion modules being electrically connected in series using the first external electrodes and the second external electrodes.
